(19) United States
(12) Patent Application Publication
(10) Pub. No.: US 2024/0201594 A1
(43) Pub. Date: Jun. 20, 2024

(54) TEMPLATE, METHOD FOR MANUFACTURING TEMPLATE, AND METHOD FOR MANUFACTURING SEMICONDUCTOR DEVICE

(71) Applicant: Kioxia Corporation, Tokyo (JP)

(72) Inventor: Ryutaro OTAHARA, Yokkaichi Mie (JP)

(21) Appl. No.: 18/459,600

(22) Filed: Sep. 1, 2023

(30) Foreign Application Priority Data
Dec. 16, 2022 (JP) 2022-201230

(51) Int. Cl. G03F 7/11; H01L 21/027

(52) U.S. Cl. CPC G03F 7/11; H01L 21/027

(57) ABSTRACT

A template includes a base material, and a mesa portion protruding from a surface of the base material. The mesa portion includes a plurality of protruding portions protruding from a reference plane of the mesa portion. The plurality of protruding portions include at least a first protruding portion and a second protruding portion, in which a protrusion amount of the second protruding portion with respect to the reference plane is smaller than a protrusion amount of the first protruding portion with respect to the reference plane. A surface area of a top surface of the second protruding portion is larger than a surface area of a top surface of the first protruding portion.

### CROSS-REFERENCE TO RELATED APPLICATION (S)

This application is based upon and claims the benefit of priority from Japanese Patent Application No. 2022-201230, filed Dec. 16, 2022, the entire contents of which are incorporated herein by reference.

### FIELD

Embodiments described herein relate generally to a template, a method for manufacturing the template, and a method for manufacturing a semiconductor device.

### BACKGROUND

In a manufacturing process of a semiconductor device, imprint processing is performed to transfer a pattern of a template to a resist film on a film to be processed to form a desired pattern on the film to be processed.

### DESCRIPTION OF THE DRAWINGS

FIG. 1 is a cross-sectional view showing a cross-sectional structure of a semiconductor device according to a first embodiment.

FIG. 2 is a cross-sectional view showing a cross-sectional structure around a memory layer of the semiconductor device according to the first embodiment.

FIG. 3 is a view schematically showing a structure of an imprint device according to the first embodiment.

FIG. 4 is a front view showing a front structure of a template according to the first embodiment.

FIG. 5 is a cross-sectional view showing an enlarged cross-sectional structure of an actual pattern and a dummy pattern of the template according to the first embodiment.

FIG. 6 is a cross-sectional view showing a cross-sectional structure of the actual pattern of the template according to the first embodiment.

FIGS. 7A and 7B are cross-sectional views showing a cross-sectional structure around a top surface of a columnar pattern according to the first embodiment.

FIG. 8A is a cross-sectional view schematically showing the wettability of the top surface of the columnar pattern according to the first embodiment with respect to a resist material. FIG. 8B is a cross-sectional view schematically showing the wettability of the top surface of a columnar pattern according to a reference example with respect to a resist material.

FIGS. 9A to 9C are cross-sectional views showing part of a manufacturing process of the semiconductor device according to the first embodiment.

FIGS. 10A to 10C are cross-sectional views showing part of the manufacturing process of the semiconductor device according to the first embodiment.

FIGS. 11A to 11F are cross-sectional views showing part of the manufacturing process of the semiconductor device according to the first embodiment.

FIGS. 12A to 12C are cross-sectional views showing part of a manufacturing process of the template according to the first embodiment.

FIGS. 13A to 13C are cross-sectional views showing part of the manufacturing process of the template according to the first embodiment.

FIGS. 14A to 14C are cross-sectional views showing part of the manufacturing process of the template according to the first embodiment.

FIGS. 15A to 15C are cross-sectional views showing part of the manufacturing process of the template according to the first embodiment.

FIGS. 16A to 16C are cross-sectional views showing part of the manufacturing process of the template according to the first embodiment.

FIGS. 17A to 17D are cross-sectional views showing part of the manufacturing process of the template according to the first embodiment.

FIGS. 18A and 18B are cross-sectional views showing part of the manufacturing process of the template according to the first embodiment.

FIGS. 19A and 19B are cross-sectional views showing how the resist material permeates between the template and a wafer according to the first embodiment.

FIGS. 20A to 20C are cross-sectional views showing part of a manufacturing process of a template according to a modification example of the first embodiment.

FIGS. 21A and 21B are cross-sectional views showing a cross-sectional structure around the top surface of a columnar pattern according to a second embodiment.

FIG. 22 is a cross-sectional view showing a cross-sectional structure of an actual pattern of a template according to another embodiment.

FIG. 23 is a cross-sectional view showing a cross-sectional structure of an actual pattern of a template according to another embodiment.

### DETAILED DESCRIPTION

Embodiments provide a template, a method for manufacturing the template, and a method for manufacturing a semiconductor device that can prevent a formation defect of a patterned resist.

In general, according to one embodiment, a template of an embodiment is a template configured to transfer a pattern to a resin applied to a substrate. The template includes a base material, and a mesa portion protruding from a surface of the base material. The mesa portion includes a plurality of protruding portions protruding from a reference plane of the mesa portion. The plurality of protruding portions include at least a first protruding portion and a second protruding portion, in which a protrusion amount of the second protruding portion with respect to the reference plane is smaller than a protrusion amount of the first protruding portion with respect to the reference plane. A surface area of a top surface of the second protruding portion is larger than a surface area of a top surface of the first protruding portion.

A method for manufacturing a template according to an embodiment is a method for manufacturing a template capable of transferring a pattern to a resin applied to a substrate, including processing a surface of a base material to form a mesa portion protruding from the base material, forming a plurality of protruding portions including a first protruding portion and a second protruding portion whose protrusion amount from a reference plane is smaller than that of the first protruding portion, on the reference plane of the mesa portion, and performing surface processing treatment on a top surface of the second protruding portion so that a surface area of the top surface of the second protruding portion is larger than a surface area of a top surface of the first protruding portion.

A method for manufacturing a semiconductor device according to the embodiment includes transferring a pattern formed on a mesa portion to an organic material applied on a substrate to form a patterned resist, and processing the substrate based on the patterned resist, by using the above template.

Hereinafter, embodiments will be described with reference to drawings. In order to facilitate understanding of the description, the same elements are designated by the same reference signs as much as possible in each drawing, and duplicate description is omitted.

### 1. First Embodiment

A template, a template manufacturing method, and a semiconductor device manufacturing method of a first embodiment will be described. A semiconductor device according to the present embodiment is a nonvolatile storage device configured as a NAND flash memory.

### 1.1 Configuration of Semiconductor Device

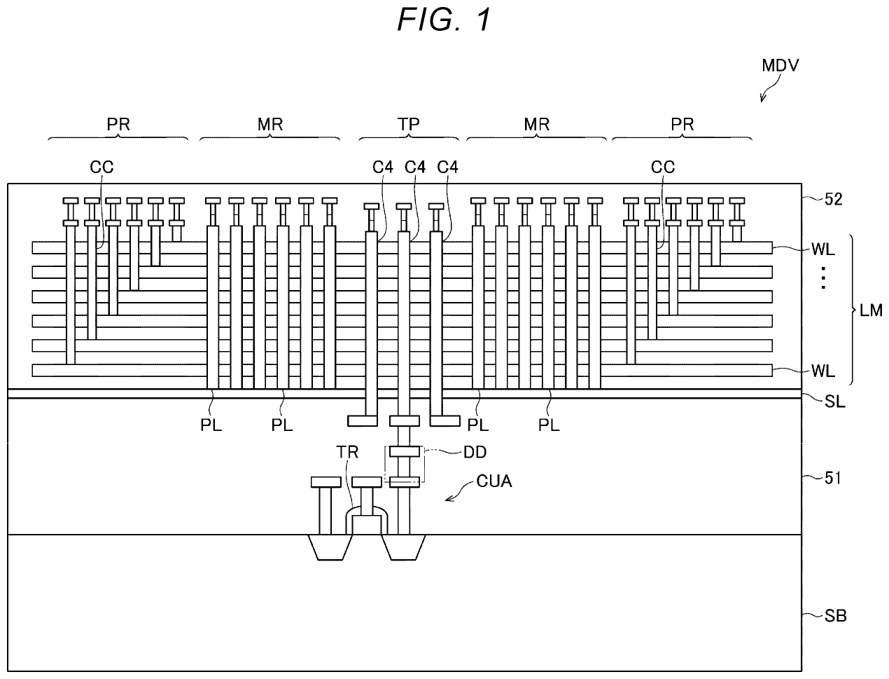

FIG. 1 is a cross-sectional view showing a schematic configuration of a semiconductor device MDV of the present embodiment. In FIG. 1, hatching indicating a cross-sectional portion is omitted in order to improve the visibility of the drawing.

As shown in FIG. 1, the semiconductor device MDV includes a peripheral circuit CUA, a source line SL, and a stacked body LM. The peripheral circuit CUA, the source line SL, and the stacked body LM are formed on a substrate SB in this order. The substrate SB is a silicon substrate or the like. The peripheral circuit CUA includes transistors TR and the like, and contributes to the electrical operation of memory cells, which will be described later. Transistor TR is formed on the substrate SB. The peripheral circuit CUA is covered with an insulating film 51. The insulating film 51 is a silicon oxide film or the like. The source line SL is formed on the insulating film 51. The source line SL is a conductive polysilicon layer or the like.

The stacked body LM is formed on the source line SL. The stacked body LM includes a plurality of stacked word lines WL. The word line WL is a tungsten layer, a molybdenum layer, or the like. An insulating layer is interposed between each of the plurality of word lines WL. The insulating layer is a silicon oxide layer or the like.

The stacked body LM includes a memory region MR, a contact region PR, and a through contact region TP. Each region MR, PR, TP is provided with a plurality of pillars PL and a plurality of contacts CC and C4. The entire stacked body LM is covered with an insulating film 52. The insulating film 52 is a silicon oxide film or the like.

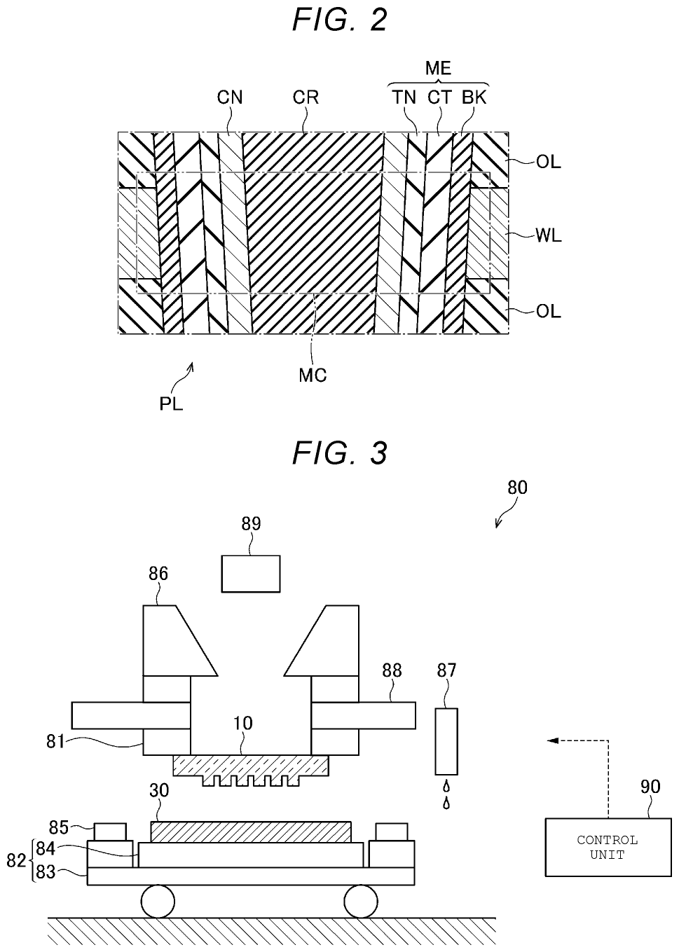

Each of the plurality of pillars PL penetrates the stacked body LM and reaches the source line SL. A detailed configuration of the pillar PL is shown in FIG. 2. As shown in FIG. 2, the pillar PL includes a memory layer ME and a channel layer CN. The memory layer ME and the channel layer CN are arranged in this order from the outer periphery of the pillar PL. The core layer CR is filled inside the channel layer CN. The memory layer ME has a multilayer structure in which the block insulating layer BK, the charge storage layer CT, and the tunnel insulating layer TN are stacked. The block insulating layer BK, the charge storage layer CT, and the tunnel insulating layer TN are arranged in this order from the outer periphery of the pillar PL. The memory layer ME is not disposed at the lower end portion of the pillar PL, and the channel layer CN provided inside the memory layer ME is connected to the source line SL.

The channel layer CN is, for example, a semiconductor layer such as a polysilicon layer or an amorphous silicon layer. The core layer CR, the tunnel insulating layer TN, and the block insulating layer BK are, for example, silicon oxide layers. The charge storage layer CT is, for example, a silicon nitride layer. A reference sign OL shown in FIG. 2 represents an insulating layer formed between the plurality of word lines WL.

With such a configuration, a plurality of memory cells MC arranged in the height direction are formed at the intersections of the pillars PL and the word lines WL. By applying a predetermined voltage from the word line WL to the memory cell MC, charges may be accumulated in the charge storage layer CT of the memory cell MC or extracted from the charge storage layer CT. Data is written to or read from the memory cell MC by accumulating charges in the charge storage layer CT or extracting charges from the charge storage layer CT. Data read from the memory cell MC is transmitted to, for example, a sense amplifier of the semiconductor device MDV via a plug provided above the pillar PL, an upper layer wiring, and the like.

Each of the plurality of contacts CC shown in FIG. 1 extends to a depth connected to one of the plurality of word lines WL provided in the stacked body LM. Each of the plurality of contacts CC is connected to the plurality of contacts C4 via upper layer wirings and plugs.

The plurality of contacts C4 extend through the stacked body LM and the source line SL to the insulating film 51 provided below the stacked body LM. Each lower end portion of the plurality of contacts C4 is connected to the transistor TR of the peripheral circuit CUA via lower layer wirings, vias, contacts, and the like in the insulating film 51.

With such a configuration, by applying a predetermined voltage from the peripheral circuit CUA to each memory cell MC through the contacts C4 and CC, the memory cell MC may be electrically operated. In the semiconductor device MDV having the configuration as described above, a configuration having a three-dimensional shape having a highly three-dimensional structure may be formed by, for example, imprint processing using a template. As a configuration having a highly advanced three-dimensional structure, for example, there are a dual damascene structure DD in which a via and a wiring for electrically connecting a contact C4 and a peripheral circuit CUA are collectively formed, the plurality of contacts CC reaching each of the word lines WL having different depths of the stacked body LM, or the like.

### 1.2 Configuration of Imprint Device

Next, the configuration of an imprint device 80 used in a manufacturing process of the semiconductor device MDV described above will be described. FIG. 3 shows a configuration example of the imprint device 80 of the present embodiment. As shown in FIG. 3, the imprint device 80 includes a template stage 81, a wafer stage 82, a reference mark 85, an alignment sensor 86, a droplet dropping device 87, a stage base 88, a light source 89, and a control unit 90. A template 10 for transferring a fine pattern onto a resist material on a wafer 30 to form a patterned resist is installed in the imprint device 80. The resist material is, for example, a photocurable organic chemical liquid that is cured by being irradiated with light.

The wafer stage 82 as a substrate stage includes a main body 83 and a wafer chuck 84. The wafer chuck 84 fixes the wafer 30 as a semiconductor substrate at a predetermined position on the main body 83. The reference mark 85 is provided on the wafer stage 82. The reference mark 85 is used for alignment when loading the wafer 30 onto the wafer stage 82.

The wafer 30 is placed on the wafer stage 82. The wafer stage 82 moves together with the placed wafer 30 in a direction parallel to the horizontal plane. The wafer stage 82 moves the wafer 30 below the droplet dropping device 87 when dropping the resist material onto the wafer 30. The wafer stage 82 moves the wafer 30 below the template 10 when performing transfer processing on the wafer 30.

The stage base 88 supports the template 10 with the template stage 81 and moves up and down (vertically) to bring the fine pattern of the template 10 into contact with the resist material on the wafer 30. The alignment sensor 86 is provided on the stage base 88. The alignment sensor 86 detects the position of the wafer 30 and the template 10 based on alignment marks provided on the wafer 30 and the template 10.

The droplet dropping device 87 is a device for dropping a resist material onto the wafer 30 by an inkjet method. The inkjet head provided in the droplet dropping device 87 has a plurality of fine holes for ejecting droplets of the resist material, and drops the droplets of the resist material onto the wafer 30. The light source 89 is, for example, a device that emits ultraviolet rays, and is provided above the stage base 88. The light source 89 emits light from above the template 10 in a state in which the template 10 is pressed against the resist material.

The control unit 90 controls the template stage 81, the wafer stage 82, the reference mark 85, the alignment sensor 86, the droplet dropping device 87, the stage base 88, and the light source 89.

### 1.3 Configuration of Template

Next, the configuration of the template 10 used in the imprint device 80 described above will be described. Here, an example of the template 10 for forming the plurality of contacts CC shown in FIG. 1 will be described.

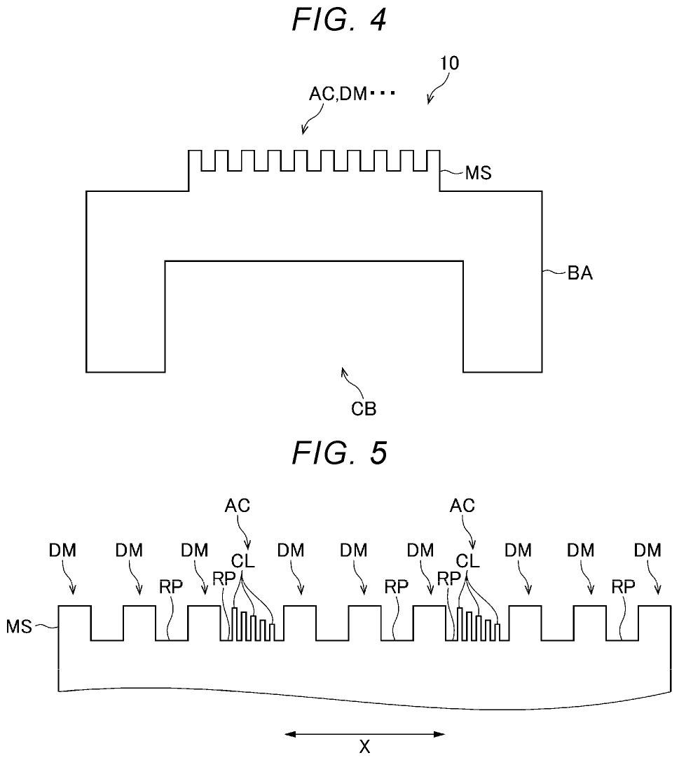

FIG. 4 schematically shows the configuration of the template 10 of the present embodiment. As shown in FIG. 4, the template 10 includes a transparent substrate BA, such as quartz.

In the present embodiment, the transparent substrate BA corresponds to a base material. The transparent substrate BA includes a mesa portion MS. The mesa portion MS protrudes from one surface of the transparent substrate BA. A counterbore CB is formed on the back side of the transparent substrate BA. As a result, the central portion of the back surface of the transparent substrate BA is recessed.

A plurality of actual patterns AC and dummy patterns DM are provided in the mesa portion MS. The plurality of actual patterns AC are patterns that are transferred to a film to be processed, which will be described later, and become a part of the configuration of the semiconductor device MDV. The dummy pattern DM is a dummy pattern that disappears without being transferred to a film to be processed, which will be described later.

FIG. 5 shows an enlarged cross-sectional structure of the actual pattern AC and the dummy pattern DM of the template 10. As shown in FIG. 5, a plurality of actual patterns AC and dummy patterns DM protrude from a reference plane RP of the mesa portion MS. The plurality of actual patterns AC are spaced apart in the direction indicated by the arrow X in the drawing, that is, the direction along the reference plane RP of the mesa portion MS. The dummy patterns DM are provided between the plurality of actual patterns AC and at the outer edge portion of the mesa portion MS.

Each of the plurality of actual patterns AC includes a plurality of columnar patterns CL with different protrusion heights from the reference plane RP. In the present embodiment, the columnar pattern CL corresponds to a protruding portion protruding from the reference plane RP of the mesa portion MS. In FIG. 5, these columnar patterns CL subsequently increase in height in one direction parallel to the X direction. The arrangement and order of arrangement of the plurality of columnar patterns CL are not limited to the example shown in FIG. 5 and may be changed freely.

In the example shown in FIG. 5, the difference in height between adjacent columnar patterns CL is, for example, about several nanometers to several hundreds of nanometers. These columnar patterns CL are formed, for example, in the shape of quadrangular columns having substantially equal cross-sectional areas orthogonal to the protrusion direction and different heights. In the mesa portion MS, these columnar patterns CL are formed, for example, by a number of tens to a hundred.

The actual pattern AC is interposed between a pair of dummy patterns DM in the direction indicated by the arrow X. The plurality of dummy patterns DM are arranged between the plurality of actual patterns AC. Each of the plurality of dummy patterns DM is formed in a convex shape. The plurality of dummy patterns DM are arranged at predetermined intervals in the direction indicated by the arrow X over the entire surface of the mesa portion MS, except for the portions where the actual patterns AC are formed.

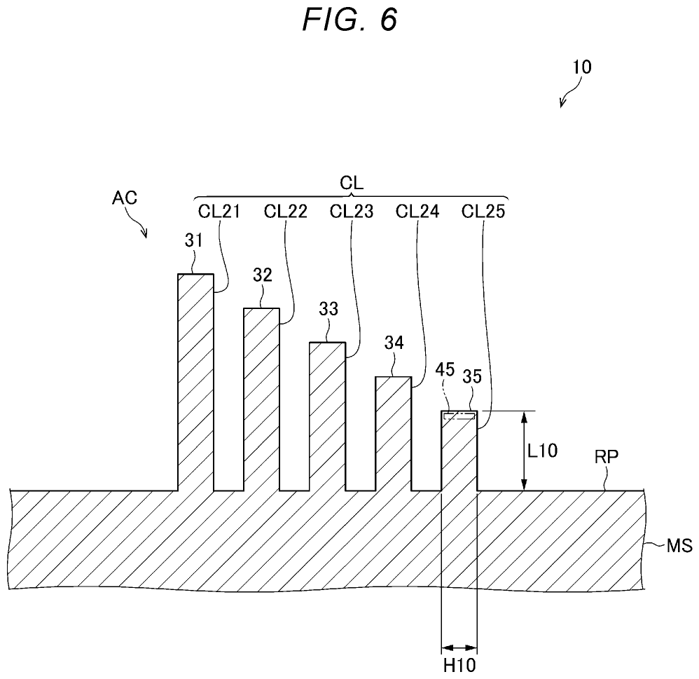

FIG. 6 shows an enlarged cross-sectional structure of the actual pattern AC of the template 10. As shown in FIG. 6, in the following, the plurality of columnar patterns CL provided in the actual pattern AC are sequentially referred to as columnar patterns CL21, CL22, CL23, CL24, and CL25 from the one having a high protrusion amount from the reference plane RP of the mesa portion MS. Each protrusion amount of the columnar patterns CL21 to CL25 includes, for example, the height from the reference plane RP of the mesa portion MS, and more specifically, the length from the reference plane RP to top surfaces 31 to 35 in the direction orthogonal to the reference plane RP. Therefore, the columnar pattern CL21 has the largest protrusion amount from the reference plane RP of the mesa portion MS. The columnar pattern CL25 has the smallest protrusion amount from the reference plane RP of the mesa portion MS. In the present embodiment, at least one of the columnar patterns CL21 to CL24 corresponds to a first protruding portion, and the columnar pattern CL25 corresponds to a second protruding portion.

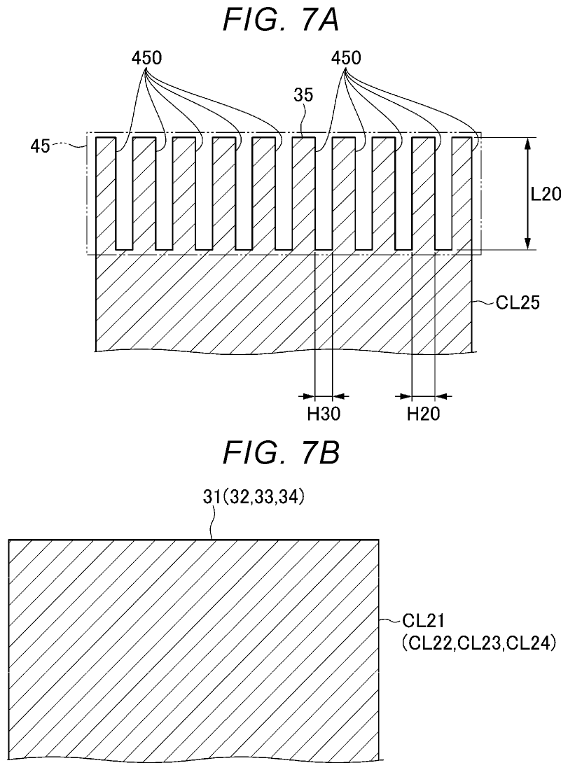

FIG. 7A shows an enlarged cross-sectional structure of the top surface 35 of the columnar pattern CL25. As shown in FIG. 7A, a fine uneven structure 45 is formed on the top surface 35 of the columnar pattern CL25 having the smallest protrusion amount. The uneven structure 45 has a plurality of projections 450 arranged at predetermined intervals. A height L20 of the projection 450 is significantly shorter than the height L10 of the columnar pattern CL25 shown in FIG. 6. A width H20 of the projection 450 shown in FIG. 7A is significantly narrower than the width H10 of the columnar pattern CL25 shown in FIG. 6. The uneven structure 45 has affinity with respect to the resist material before curing.

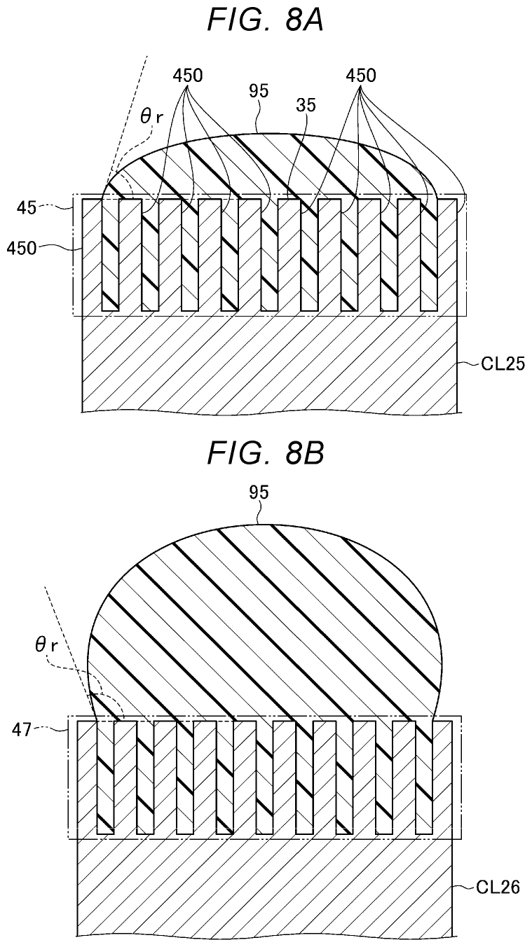

Specifically, as shown in FIG. 8A, when an angle θr formed by a surface parallel to the top surface 35 of the columnar pattern CL25 and a liquid surface of an outer edge of a resist material 95 before curing is set as a “contact angle θr”, the contact angle θr is changed by, for example, the height L10 and width H20 of the projection 450 shown in FIG. 7A, and a width H30 of a gap formed between the projections 450, and the like. For example, depending on the respective values of the height L10 and width H20 of the projections 450 and the width H30 of the gap formed between the projections 450, the contact angle θr may be larger than 90 degrees as shown in FIG. 8B, such as a columnar pattern CL26 of a reference example having an uneven structure 47 as shown in FIG. 8B. In this case, the affinity of the top surface 35 of the columnar pattern CL25 with respect to the resist material 95 before curing is low. On the other hand, on the top surface 35 of the columnar pattern CL25 of the present embodiment, the contact angle θr is 90 degrees or less as shown in FIG. 8A. Thus, in the template 10 of the present embodiment, the affinity of the top surface 35 of the columnar pattern CL25 with respect to the resist material 95 before curing is high.

As described above, in the template 10 of the present embodiment, the shape of the uneven structure 45 is set so that the top surface 35 of the columnar pattern CL25 has wettability such that the contact angle θr is 90 degrees or less with respect to the resist material 95 before curing. Specifically, the height L10 and width H20 of the projection 450 in the uneven structure 45, the width H30 of the gap formed between the projections 450, and the like are set. More preferably, the shape of the uneven structure 45 may be set so that the top surface 35 of the columnar pattern CL25 has wettability such that the contact angle θr is 65 degrees or less with respect to the resist material 95 before curing.

FIG. 7B shows an enlarged cross-sectional structure of the top surface 31 of the columnar pattern CL21. As shown in FIG. 7B, the uneven structure 45 shown in FIG. 7A is not formed on the top surface 31 of the columnar pattern CL21. Similarly, the uneven structure 45 is not formed on each of the top surfaces of the other columnar patterns CL22 to CL24.

Due to the presence or absence of such the uneven structure 45, the surface area of the top surface 35 of the columnar pattern CL25 is larger than the surface areas of the top surfaces 31 to 34 of the other columnar patterns CL21 to CL24.

### 1.4 Method for Manufacturing Semiconductor Device

Next, a method for manufacturing the semiconductor device MDV using the imprint device 80 described above will be described with reference to FIGS. 9A to 11F.

FIGS. 9A to 11F sequentially show part of the method for manufacturing the semiconductor device MDV of the present embodiment. When manufacturing the semiconductor device MDV, first, as shown in FIG. 9A, a film to be processed PF is formed on a base film UF. The base film UF is the insulating film 51 covering the peripheral circuit CUA in the semiconductor device MDV described above, the source line SL formed on the insulating film 51, and the like. The film to be processed PF is, for example, a multilayer film in which a plurality of nitride layers and oxide layers are alternately stacked. In the film to be processed PF, the nitride layer is later replaced with a tungsten layer or the like to become the stacked body LM of the semiconductor device MDV described above. In the present embodiment, the entire film to be processed PF and base film UF correspond to the wafer 30 used in the imprint device 80 shown in FIG. 3.

Subsequently, a resist material 91 is formed on the film to be processed PF. The resist material 91 is, for example, a photocurable resin film or the like, and is formed by coating the film to be processed PF with a photocurable resin film or the like by using a spin coating method or the like. At this time, the resist material 91 is formed, for example, to cover the entire region on the film to be processed PF to which the actual patterns AC and the dummy patterns DM in the mesa portion MS of the template 10 are transferred. The resist material 91 is in an uncured state at this stage. In the present embodiment, the resist material 91 corresponds to the organic material.

Subsequently, in order to transfer the plurality of columnar patterns CL of the template 10 to the resist material 91, the template 10 is opposed to the resist material 91 so that the surface on which the columnar patterns CL are formed is directed to the side of the film to be processed PF. Subsequently, as shown in FIG. 9B, the columnar pattern CL of the template 10 is pressed against the resist material 91 on the film to be processed PF. At this time, a slight gap is provided between the columnar pattern CL having the largest protrusion amount and the film to be processed PF so that the mesa portion MS of the template 10 does not come into contact with the film to be processed PF.

By maintaining this state for a predetermined time, the resist material 91 permeates between the plurality of columnar patterns CL of the template 10 and between the plurality of dummy patterns DM. After the resist material 91 spreads between the columnar patterns CL and between the dummy patterns DM, while the template 10 is pressed against the resist material 91, the template 10 is transmitted to irradiate the resist material 91 with light such as ultraviolet light. Thereby, the resist material 91 is cured.

Subsequently, as shown in FIG. 9C, when the template 10 is released, a patterned resist 91p is formed whose upper surface is a contact surface with the reference plane RP of the mesa portion MS the template 10. A plurality of contact patterns PP and a plurality of recess patterns DP are formed on the contact surface of the patterned resist 91p.

The plurality of contact patterns PP are patterns obtained by transferring the actual patterns AC of the template 10. Each of the plurality of contact patterns PP is arranged apart from each other. Each of the plurality of contact patterns PP has a plurality of hole patterns CP to which the columnar patterns CL of the template 10 are transferred.

The plurality of recess patterns DP are patterns to which the dummy patterns DM are transferred. Each of the plurality of recess patterns DP is formed in a recess shape. Each of the plurality of contact patterns PP is interposed between the plurality of recess patterns DP, and the plurality of recess patterns DP are interposed between the plurality of contact patterns PP.

Since the resist material 91 is cured with a gap provided between the template 10 and the film to be processed PF as described above, the patterned resist 91p has a resist residual film 91r at the bottom of the most deeply formed hole pattern CP among the plurality of hole patterns CP. Similarly, the patterned resist 91p has the resist residual film 91r at the bottom of each recess pattern DP.

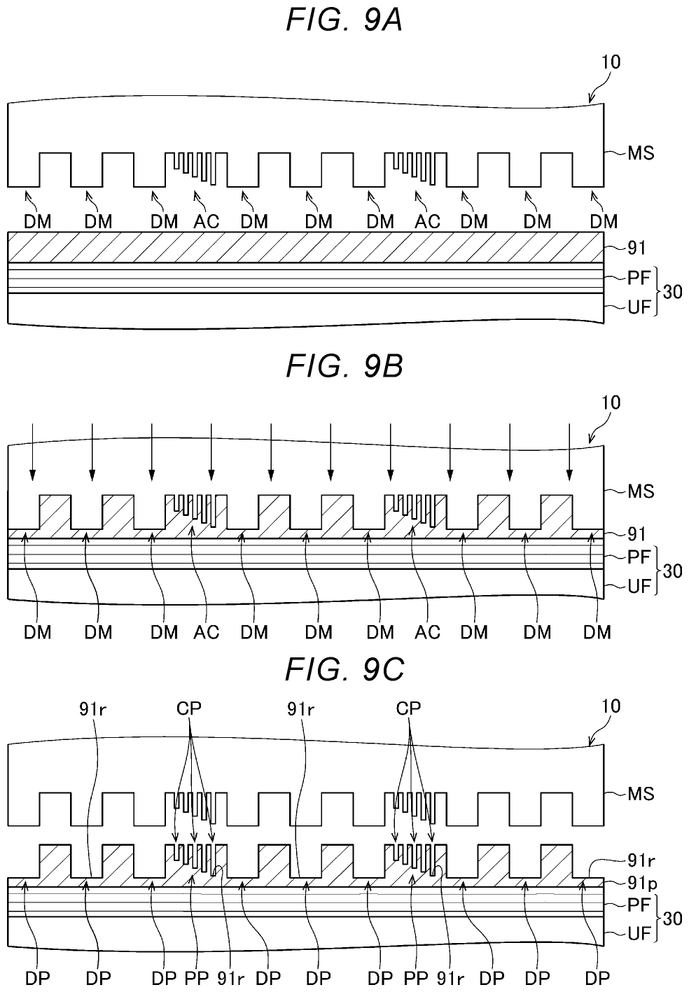

Subsequently, as shown in FIG. 10A, a resist film 92 covers the patterned resist 91p. The resist film 92 is a photosensitive positive resist film or the like used in photolithography or the like, and is formed by applying a positive resist material onto the patterned resist 91p by using, for example, a spin coating method.

Subsequently, as shown in FIG. 10B, a photomask 40 is disposed opposed to the resist film 92 in order to expose a part of the resist film 92. The photomask 40 includes a transparent substrate 41 and a light shielding film pattern 42p. The light shielding film pattern 42p includes a plurality of openings 42op. The plurality of openings 42op are arranged at positions vertically overlapping with the plurality of contact patterns PP formed in the patterned resist 91p on the film to be processed PF. The plurality of openings 42op are larger than the regions in which the plurality of contact patterns PP are formed, and the whole of the individual contact patterns PP is disposed in a lower position of the opening 42op.

Subsequently, in a state in which the photomask 40 is opposed to the resist film 92, the resist film 92 is irradiated with exposure light such as ultraviolet light transmitted through the openings 42op of the photomask 40. As a result, a portion of the resist film 92 covering the patterned resist 91p, which covers the plurality of contact patterns PP is exposed.

Subsequently, the partially exposed resist film 92 is developed to form a patterned resist 92p as shown in FIG. 10C. The patterned resist 92p has an opening 92op at a position overlapping with the contact pattern PP of the patterned resist 91p. By forming the patterned resist 92p, a portion of the patterned resist 91p covered with the resist film 92, in which the contact pattern PP is formed, is exposed from the opening 92op of the patterned resist 92p.

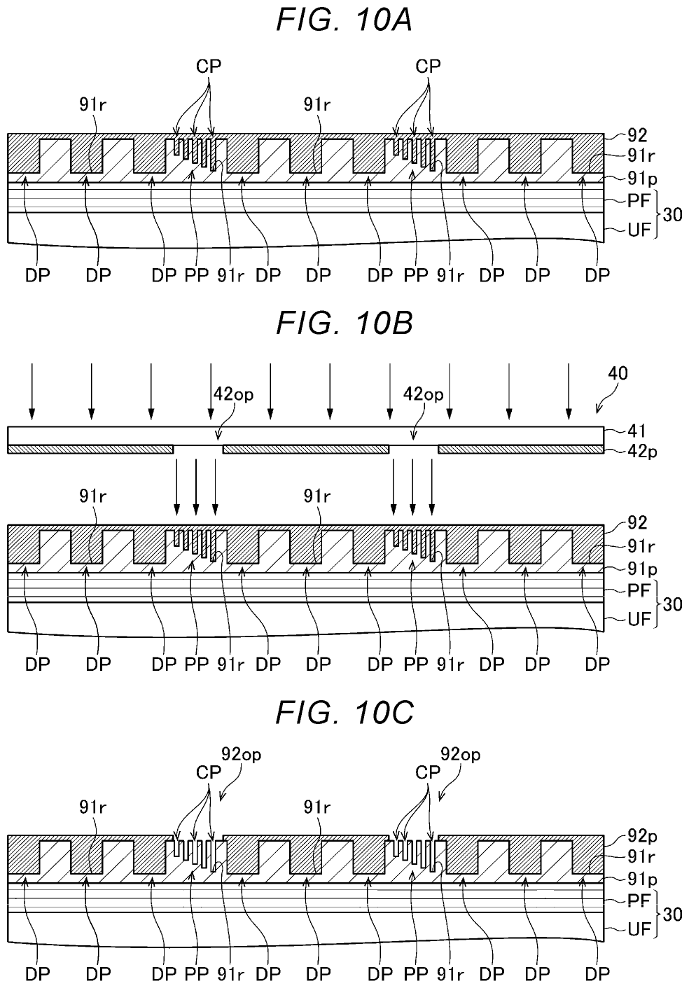

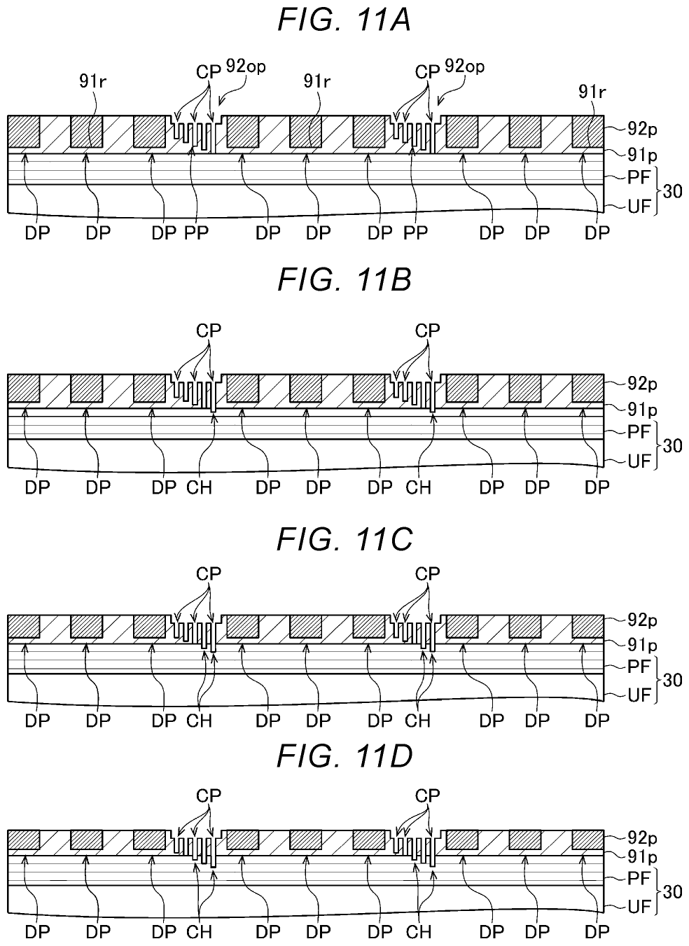

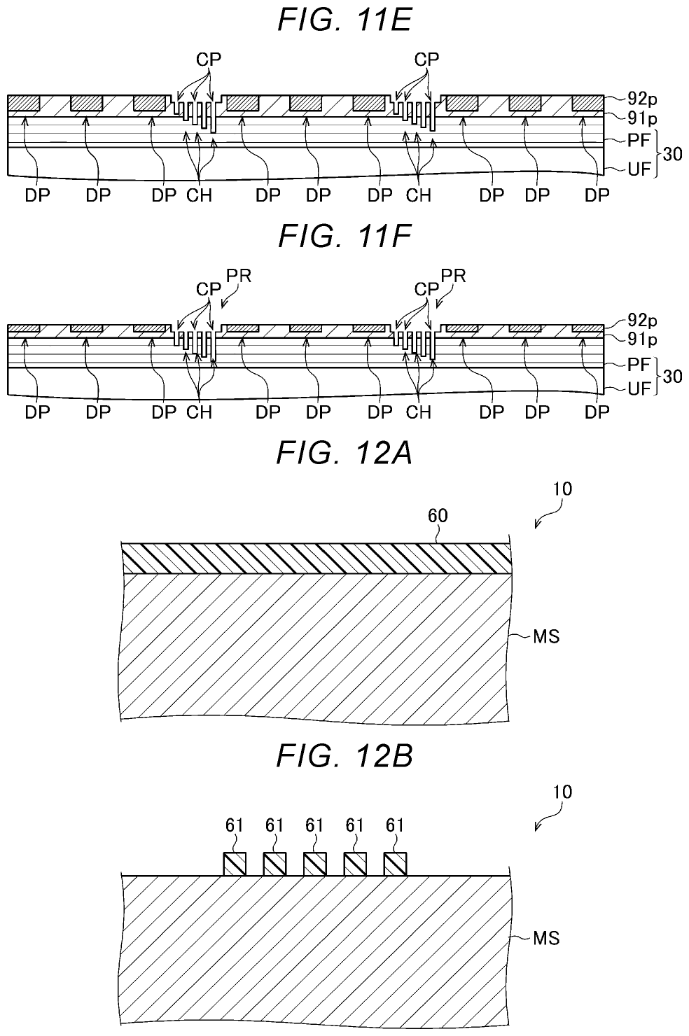

Subsequently, as shown in FIG. 11A, a portion of the resist residual film 91r, which is provided at the bottom of the deepest hole pattern CP is removed by using oxygen plasma or the like. As a result, a portion of the upper surface of the film to be processed PF, which is provided at the bottom of the deepest hole pattern CP, is exposed. The film thickness of the patterned resists 91p and 92p is reduced as a whole.

Subsequently, as shown in FIG. 11B, the film to be processed PF is processed through the patterned resists 91p and 92p. As a result, the film to be processed PF exposed from the patterned resist 91p is removed, and the contact hole CH corresponding to the deepest hole pattern CP is formed. The bottom of the hole patterns CP arranged next to the deepest hole patterns CP in the resist residual film 91r are removed by using oxygen plasma or the like, thereby newly exposing the film to be processed PF. At this time, the film thickness of the patterned resist 92p also decreases together with the patterned resist 91p.

Subsequently, as shown in FIG. 11C, the processing of the film to be processed PF is further continued through the patterned resists 91p and 92p. As a result, the upper surface of the film to be processed PF newly exposed from the patterned resist 91p is removed to form a new contact hole CH. The contact hole CH previously formed in the film to be processed PF is formed deeper.

Thereafter, by further continuing the processing of the film to be processed PF through the patterned resists 91p and 92p and the film reduction of the patterned resists 91p and 92p by oxygen plasma or the like, a plurality of contact holes CH having different depths are formed on the film to be processed PF as shown in FIGS. 11D to 11F. Meanwhile, the plurality of recess patterns DP are not transferred to the film to be processed PF. After the processing shown in FIG. 11F is completed, processing of removing the remaining patterned resists 91p and 92p is performed.

A region in which the plurality of contact holes CH are formed as described above becomes the contact region PR in the semiconductor device MDV shown in FIG. 1. Thus, the pattern forming process using the template 10 is completed. Thereafter, for example, the pillars PL shown in FIG. 1 are formed between the plurality of contact regions PR formed in the film to be processed PF. The stacked body LM in which a plurality of word lines WL and a plurality of insulating layers OL are alternately stacked is formed by performing replacement processing of replacing the silicon nitride layer of the film to be processed PF having a multilayer structure with the word lines WL such as a tungsten layer.

Furthermore, the sidewall of the plurality of contact holes CH formed by using the template 10 is covered with an insulating layer, and the inside of the insulating layer is filled with a metal layer to form the plurality of contacts CC respectively connected to the word lines WL having different depths. As described above, the semiconductor device MDV of the present embodiment is manufactured. When replacement processing of the film to be processed PF is performed, the plurality of contact holes CH formed may be filled with a sacrificial layer. Alternatively, the replacement processing of the film to be processed PF may be performed after filling the plurality of contact holes CH with a metal layer.

### 1.5 Method for Manufacturing Template

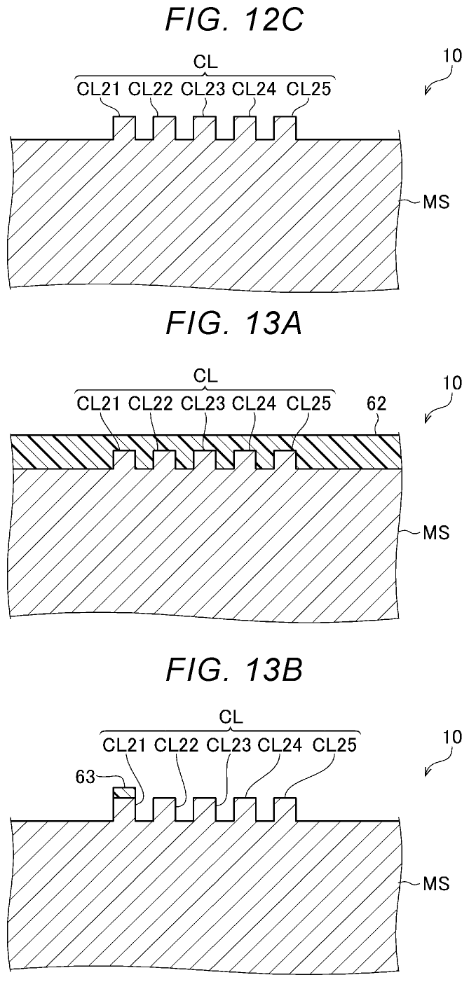

Next, a method for manufacturing the template 10 will be described. FIGS. 12A to 18B show part of the method for manufacturing the template 10 of the present embodiment, particularly the procedure for forming the actual pattern AC of the template 10.

When forming the actual pattern AC, first, as shown in FIG. 12A, after a resist material 60 is applied on the surface of the mesa portion MS of the template 10, the resist material 60 is cured and processed to form a patterned resist 61 shown in FIG. 12B on the surface of the template 10. As a method for processing the resist material 60 to form the patterned resist 61 as shown in FIGS. 12A to 12B, electron beam writing, optical lithography, or the like may be used.

Subsequently, a plurality of columnar patterns CL21 to CL25 shown in FIG. 12C are formed on the surface of the template 10 by performing etching processing on the template 10 by using the patterned resist 61 shown in FIG. 12B as a hard mask. As the etching processing, dry etching using tetrafluoromethane (CF), wet etching using hydrogen fluoride (HF), or the like may be used. When the resist material 60 remains on the surface of the template 10 after the etching processing, further, the remaining resist material 60 may be removed from the template 10 by ashing, removing liquid or the like.

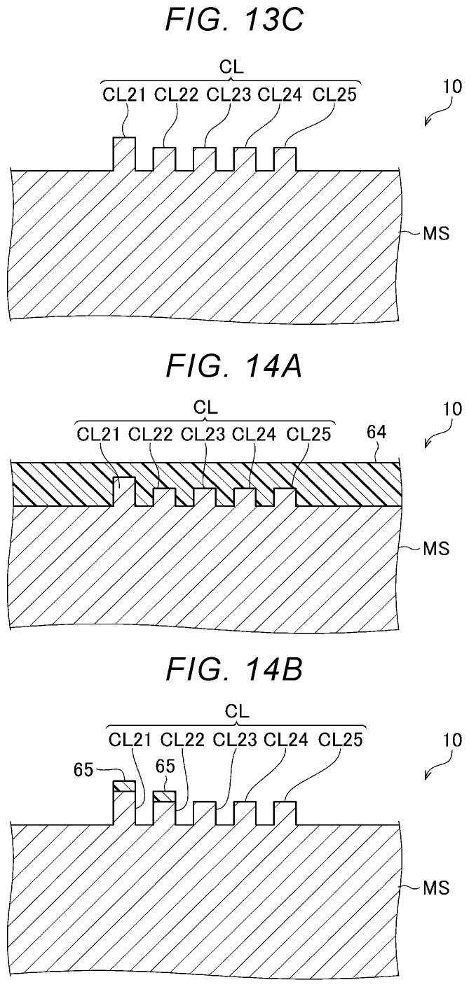

Subsequently, after a resist material 62 is applied on the surface of the template 10 as shown in FIG. 13A, the resist material 62 is processed by optical lithography or the like to form a patterned resist 63 as shown in FIG. 13B. The patterned resist 63 has, for example, a pattern shape in which the resist material remains only on the top surface of one columnar pattern CL21. Next, by using the patterned resist 63 shown in FIG. 13B as a hard mask, the template 10 is subjected to etching processing such as dry etching. As a result, as shown in FIG. 13C, the plurality of columnar patterns CL22 to CL25 having the same protrusion amount and the columnar pattern CL21 having a protrusion amount larger than those may be formed on the surface of the template 10.

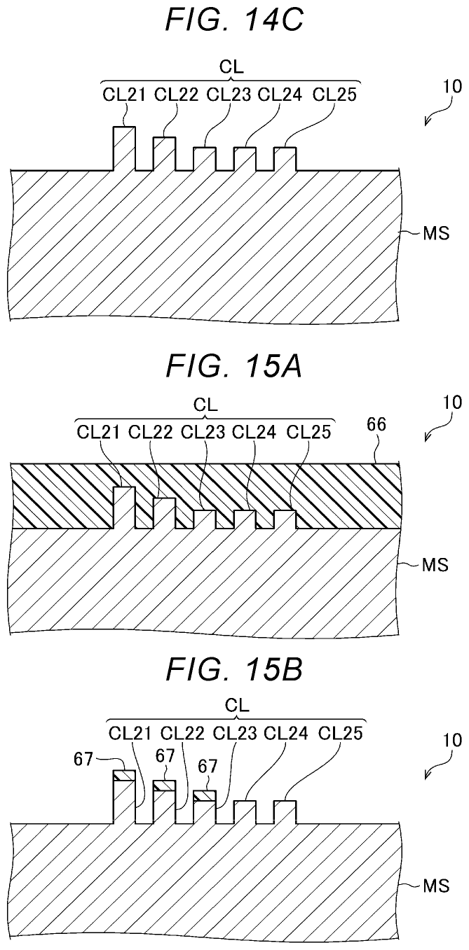

Subsequently, as shown in FIG. 14A, after a resist material 64 is applied on the surface of the template 10, the resist material 64 is cured and processed by optical lithography or the like to form a patterned resist 65 as shown in FIG. 14B. The patterned resist 65 has a pattern shape such that the resist material remains on the top surfaces of the two columnar patterns CL21 and CL22. Next, by using the patterned resist 65 shown in FIG. 14B as a hard mask, the template 10 is subjected to etching processing such as dry etching. As a result, as shown in FIG. 14C, the plurality of columnar patterns CL23 to CL25 having the same protrusion amount, the columnar pattern CL22 having a protrusion amount larger than those, and the columnar pattern CL21 having a protrusion amount larger than the columnar pattern CL22 may be formed on the surface of the template 10.

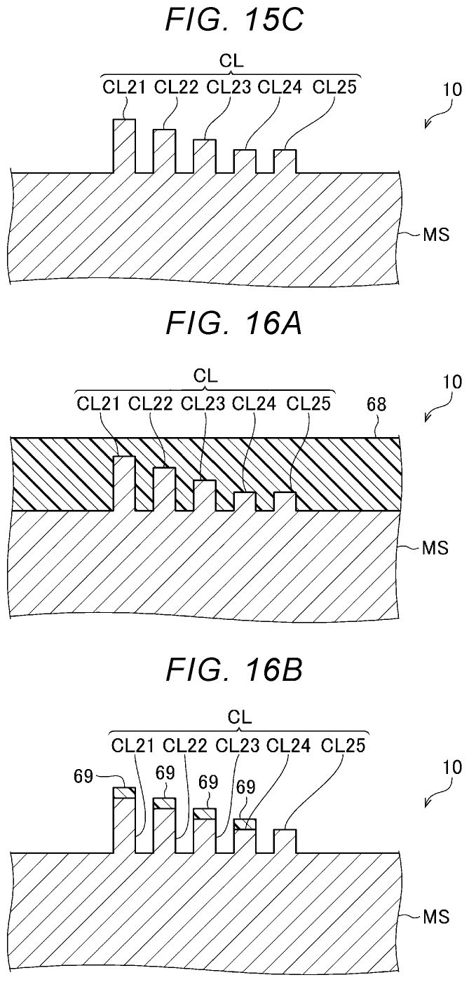

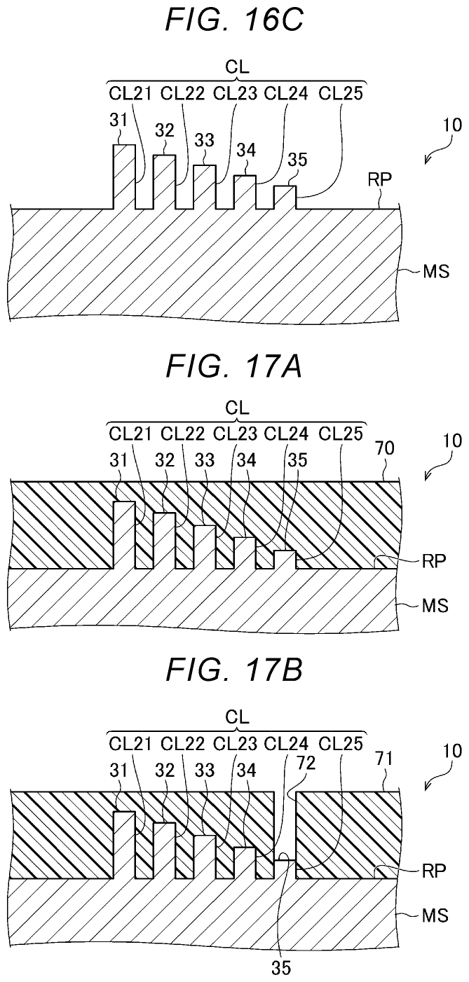

Thereafter, by increasing the number of projections forming a patterned resist one by one, the protrusion amount of the columnar patterns CL21 to CL25 is subsequently changed. That is, as shown in FIGS. 15A and 15B, after a resist 66 is applied and a patterned resist 67 is formed, the template 10 as shown in FIG. 15C is formed by performing etching processing such as dry etching on the template 10. Subsequently, as shown in FIGS. 16A and 16B, after a resist 68 is applied and a patterned resist 69 is formed, the template 10 as shown in FIG. 16C is formed by performing etching processing such as dry etching on the template 10. In the template 10 shown in FIG. 16C, the columnar patterns CL21 to CL25 are formed so that the protrusion amount gradually decreases in this order. Also, the surface of the mesa portion MS of the template 10 at this time forms the reference plane RP.

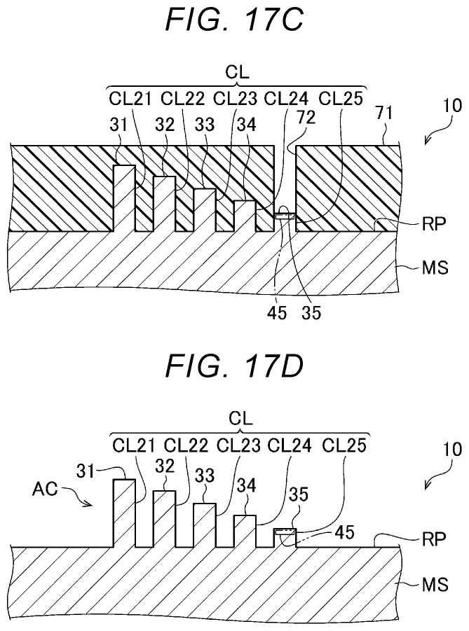

Subsequently, the fine uneven structure 45 as shown in FIG. 7A is formed on the top surface 35 of the columnar pattern CL25. Specifically, as shown in FIG. 17A, after a resist material 70 is applied to the surface of the template 10, and then the resist material 70 is processed by optical lithography or the like to form a patterned resist 71 shown in FIG. 17B. This patterned resist 71 has a processed hole 72 in the portion of the columnar pattern CL25. The top surface 35 of the columnar pattern CL25 is exposed through this processed hole 72.

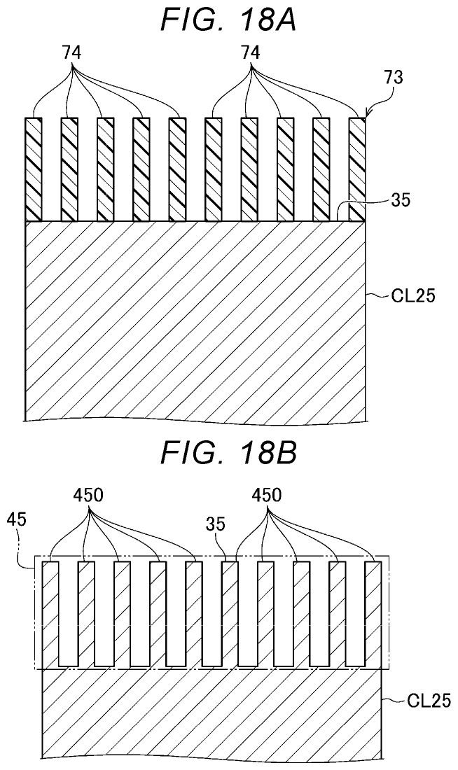

When forming the patterned resist 71 as shown in FIG. 17B by optical lithography or the like, at the position corresponding to the top surface 35 of the columnar pattern CL25, the processing of forming a patterned resist 73 as shown in FIG. 18A is also simultaneously performed. The patterned resist 73 includes a plurality of fine projections 74. Each projection 74 protrudes from the top surface 35 of the columnar pattern CL25. The plurality of projections 74 are arranged at predetermined intervals from each other.

Subsequently, etching processing such as dry etching is performed on the template 10 by using the patterned resist 71 shown in FIG. 17B and the patterned resist 73 shown in FIG. 18A as a hard mask. As a result, the top surface 35 of the columnar pattern CL25 exposed from the processed hole 72 is processed. Specifically, by using the patterned resist 73 as shown in FIG. 18A as a hard mask, etching processing is performed on the top surface 35 of the columnar pattern CL25 to form the uneven structure 45 on the top surface 35 of the columnar pattern CL25 as shown in FIGS. 17C and 18B. The uneven structure 45 has the plurality of projections 450 arranged at predetermined intervals.

Subsequently, processing of removing the patterned resist 71 from the surface of the template 10 shown in FIG. 17C is performed. As a result, the columnar patterns CL21 to CL25, in other words, the actual pattern AC are formed on the surface of the template 10, as shown in FIG. 17D.

Thus, the formation of the actual pattern AC on the template 10 is completed.

1.6 Actions and Effects when Using Template of Present Embodiment

When the semiconductor device MDV is manufactured through the process shown in FIGS. 9A to 11F, when the template 10 is pressed against the resist material 91 as the process shown in FIGS. 9A and 9B, the resist material 91 may not be properly filled in the portion of the actual pattern AC.

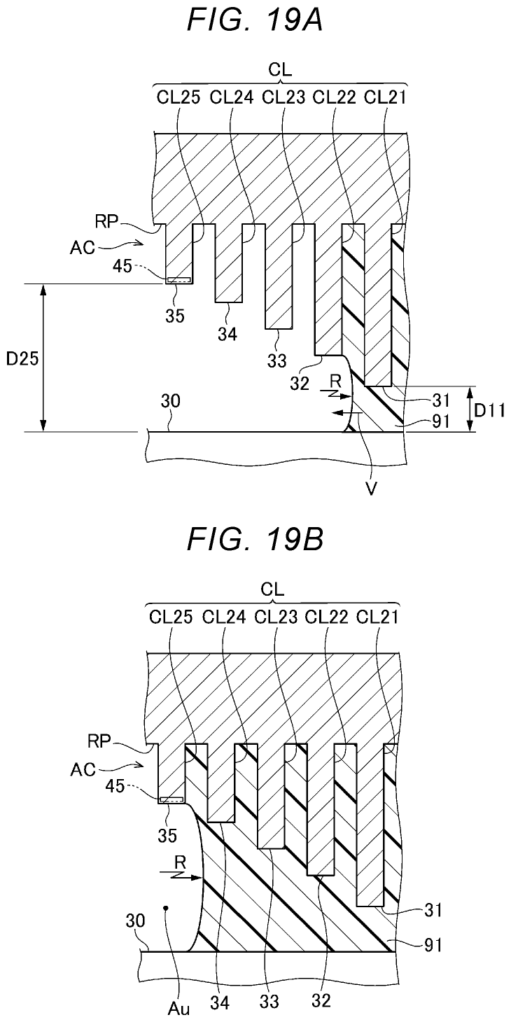

Specifically, when the template 10 is pressed against the resist material 91, the resist material 91 penetrates from the columnar pattern CL21 toward the columnar pattern CL25 as indicated by the arrow V in FIG. 19A, for example. At this time, the resist material 91 permeates into the gaps formed between the columnar patterns CL21 to CL25 based on the capillary force.

This capillary force AP may be obtained, for example, from the following Young's formula f1. In the formula f1, γ is the surface tension of the resist material 91, θr is the contact angle described above, and R is the curvature radius of the resist material 91.

$$Δ P = \frac{2 {γcosθ}_{r}}{R} \qquad ( f1 )$$

As is clear from this formula f1, as a curvature radius R of the resist material 91 decreases, a capillary force AP increases. On the other hand, as the curvature radius R of the resist material 91 increases, the capillary force AP decreases.

The curvature radius R of the resist material 91 has a correlation with the distance from the top surfaces 31 to 35 of the columnar patterns CL21 to CL25 to the surface of the wafer 30. For example, as shown in FIG. 19A, when the surface of the resist material 91 is positioned between the top surface 31 of the columnar pattern CL21 and the surface of the wafer 30, since the curvature radius R of the resist material 91 becomes relatively small, the capillary force AP becomes larger. On the other hand, as shown in FIG. 19B, when the surface of the resist material 91 is positioned between the columnar pattern CL25 and the surface of the wafer 30, since the curvature radius R of the resist material 91 is relatively large, the capillary force AP becomes smaller. In the template 10 of the present embodiment, a distance D11 from the top surface 31 of the columnar pattern CL21 having the largest protrusion amount to the surface of the wafer 30 is about 20 [nm], and a distance D25 from the top surface 35 of the columnar pattern CL25 having the smallest protrusion amount to the surface of the wafer 30 is about 230 [nm].

Considering the relationship between the curvature radius R of the resist material 91 and the capillary force AP, as the resist material 91 penetrates from the columnar pattern CL21 toward the columnar pattern CL25 as shown by the arrow V in FIG. 19A, the capillary force AP is reduced. As a result, when the resist material 91 flows into the vicinity of the columnar pattern CL25, the flow velocity of the resist material 91 is reduced, and the penetration of the resist material 91 becomes difficult. Therefore, as shown in FIG. 19B, an unfilled region Au, which is not filled with the resist material 91, is likely to be formed in the vicinity of the columnar pattern CL25. This causes a formation defect in the patterned resist 91p that is formed when the resist material 91 is cured.

By the way, Wenzel's theory is known that surface roughness affects wettability. According to this theory, a surface on which minute uneven portions or the like are formed is easier to get wet than a smooth surface. When applying this Wenzel's theory to the above formula f1, the above formula f1 may be transformed into the following formula f2. In the formula f2, A is the area of the surface on which minute uneven portions or the like are formed.

$$Δ P = \frac{2 {γAcosθ}_{r}}{R} \qquad ( f2 )$$

As is clear from this formula f2, as the area of the surface on which minute uneven portions are formed increases, the capillary force AP increases.

In this regard, in the template 10 of the present embodiment, as shown in FIG. 7A, the uneven structure 45 is formed on the top surface 31 of the columnar pattern CL25, and therefore the surface area of the top surface 31 of the columnar pattern CL25 is larger than the surface area of the respective top surfaces 31 to 34 of the other columnar patterns CL21 to CL24, in other words, the surface area of the smooth surface. Therefore, as shown in FIG. 19B, when the resist material 91 penetrates the vicinity of the columnar pattern CL25, a larger capillary force AP may be applied to the resist material 91. As a result, since the resist material 91 more easily permeates beyond the columnar pattern CL25, the resist material 91 is easily filled. Therefore, since it is difficult to form the unfilled region Au as shown in FIG. 19B, the formation defect of the patterned resist 91p can be prevented.

In the template 10 of the present embodiment, the top surface 31 of the columnar pattern CL25 is provided with the uneven structure 45 that is not formed on the other columnar patterns CL21 to CL24.

According to this configuration, it is possible to easily implement a structure in which the surface area of the top surface 35 of the columnar pattern CL25 is larger than the surface area of the respective top surfaces 31 to 34 of the columnar patterns CL21 to CL24.

In the template 10 of the present embodiment, as shown in FIGS. 6 and 7A, the height L20 of the projection 450 provided in the uneven structure 45 is shorter than the height L10 of the columnar pattern CL25. Also, the width H20 of the projection 450 provided in the uneven structure 45 is narrower than the width H10 of the columnar pattern CL25.

According to this configuration, since the top surface 35 of the columnar pattern CL25 tends to have an affinity with respect to the resist material 91, the above-described capillary force AP is easily applied to the resist material 91. As a result, since the unfilled region Au is less likely to be formed in the resist material 91, a formation defect of the patterned resist 91p is less likely to occur.

The top surface 35 of the columnar pattern CL25 has wettability such that the contact angle θr with respect to the resist material 91 is 90 degrees or less. More preferably, the top surface 35 of the columnar pattern CL25 has wettability such that the contact angle θr with respect to the resist material 91 is 65 degrees or less.

According to this configuration, since the top surface 35 of the columnar pattern CL25 tends to have an affinity with respect to the resist material 91, the capillary force AP is easily applied to the resist material 91. As a result, since the unfilled region Au is less likely to be formed in the resist material 91, a formation defect of the patterned resist 91p is less likely to occur.

In the method for manufacturing the template 10 of the present embodiment, the surface of the transparent substrate BA is processed to form the mesa portion MS protruding from the transparent substrate BA. Subsequently, the columnar patterns CL21 to CL25 are formed on the reference plane RP of the mesa portion MS, and surface processing treatment is performed on the top surface 35 of the columnar pattern CL25. The surface processing treatment is surface processing treatment for increasing the surface area of the top surface 35 of the columnar pattern CL25 over the surface area of the respective top surfaces 31 to 34 of the columnar patterns CL21 to CL24, and specifically, is etching processing or the like for forming the uneven structure 45 on the top surface 35 of the columnar pattern CL25.

According to this configuration, it is possible to easily implement a structure in which the surface area of the top surface 35 of the columnar pattern CL25 is larger than the surface area of the respective top surfaces 31 to 34 of the columnar patterns CL21 to CL24.

### 1.7 Modification Example of Method for Manufacturing Template

Next, a modification example of a method for manufacturing the template 10 according to the first embodiment will be described. In the above embodiment, by performing the process shown in FIGS. 12A to 16C using electron beam writing, optical lithography, or the like, the template 10 as shown in FIG. 16C is formed from the template 10 as shown in FIG. 12A. On the other hand, in the present modification example, the template 10 as shown in FIG. 16C is formed from the template 10 shown in FIG. 12A by using nanoimprint processing.

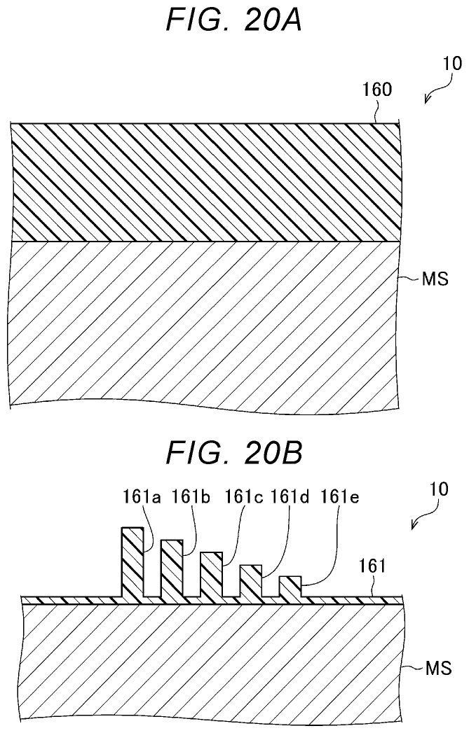

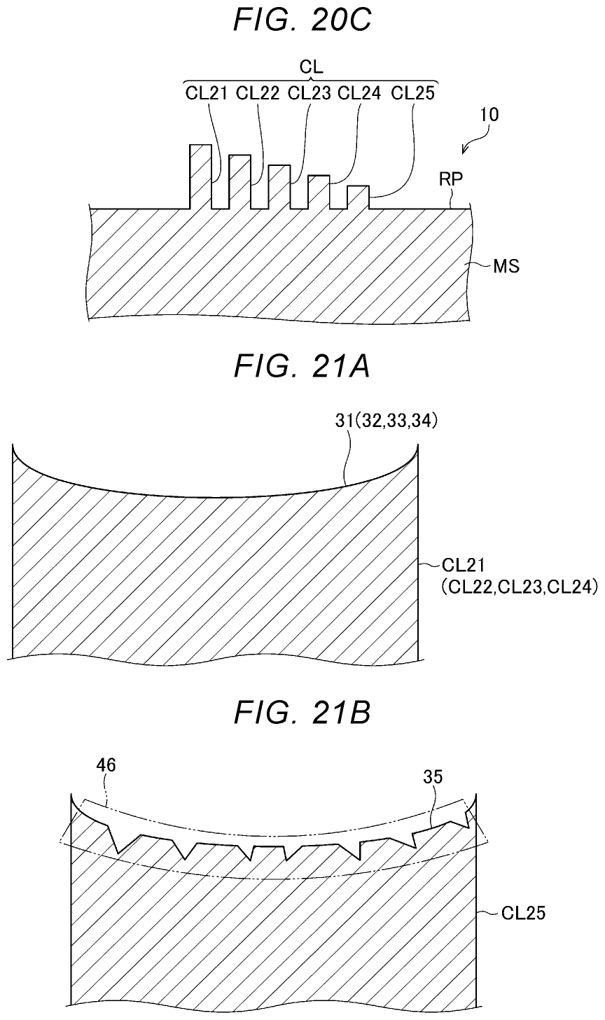

Specifically, in the method for manufacturing the template 10 of the present modification example, first, as shown in FIG. 20A, after a resist material 160 before curing is applied on the surface of the mesa portion MS of the template 10, a patterned resist 161 as shown in FIG. 20B is formed on the surface of the template 10 by using a predetermined imprint device. This patterned resist 161 has a plurality of projections 161a to 161e arranged at predetermined intervals. The plurality of projections 161a to 161e are formed so that the protrusion amount gradually decreases in this order.

Subsequently, by using the patterned resist 161 as a hard mask, the template 10 is subjected to etching processing such as dry etching. Thereby, the template 10 as shown in FIG. 20C may be formed. In the template 10 shown in FIG. 20C, the columnar patterns CL21 to CL25 are formed so that the protrusion amount gradually decreases in this order.

Thereafter, the actual pattern AC may be formed on the template 10 by performing the process shown in FIGS. 17A to 17C.

According to a manufacturing method of the present modification example, when compared with the case of using the manufacturing method shown in FIGS. 12A to 16C, the plurality of columnar patterns CL21 to CL25 having different protrusion amounts as shown in FIG. 20C may be more easily formed on the template 10.

### 2. Second Embodiment

Next, the template 10 of a second embodiment, the method for manufacturing the template 10, and the method for manufacturing the semiconductor device MDV will be described. Differences from the template 10 of the first embodiment, the method for manufacturing the template 10, and the method for manufacturing the semiconductor device MDV will be mainly described below.

### 2.1 Configuration of Template

The template 10 of the first embodiment increases the surface area of the top surface 35 of the columnar pattern CL25 by forming the uneven structure 45 as shown in FIG. 7A on the top surface 35 of the columnar pattern CL25. Instead, in the template 10 of the present embodiment, the surface area of the top surface 35 of the columnar pattern CL25 is increased by roughening the top surface 35 of the columnar pattern CL25. Specifically, the processing is performed as follows.

FIG. 21A shows an enlarged cross-sectional structure of the top surface 31 of the columnar pattern CL21. FIG. 21B shows an enlarged cross-sectional structure of the top surface 35 of the columnar pattern CL25.

When the columnar pattern CL21 is formed through the process shown in FIGS. 12A to 15C above, by etching the top surface 31 of the columnar pattern CL21, the top surface 31 of the columnar pattern CL21 is formed into a curved shape, for example, as shown in FIG. 21A. The top surfaces 32 to 34 of the columnar patterns CL22 to CL24 also have the same or similar shape as the top surface 31 of the columnar pattern CL21 shown in FIG. 21A, respectively.

On the other hand, as shown in FIG. 21B, the top surface 35 of the columnar pattern CL25 of the present embodiment has a curved shape and is roughened similarly to the top surface 31 of the columnar pattern CL21. Thereby, the surface roughness of the top surface 35 of the columnar pattern CL25 is larger than the surface roughness of the respective top surfaces 31 to 34 of the other columnar patterns CL21 to CL24. Hereinafter, the roughened structure formed on the top surface 35 of the columnar pattern CL25 is referred to as a “roughened surface structure 46”.

### 2.2 Method for Manufacturing Template

Next, a method for manufacturing the template 10 according to the present embodiment will be described. When manufacturing the template 10 of the present embodiment, when a patterned resist 71 as shown in FIG. 17B is formed by optical lithography or the like, the top surface 35 of the columnar pattern CL25 is exposed from the processed hole 72 without forming a patterned resist 73 as shown in FIG. 18A on the top surface 35 of the columnar pattern CL25. At this stage, the top surface 35 of the columnar pattern CL25 has a curved shape like the top surfaces 31 to 34 of the other columnar patterns CL21 to CL24 as shown in FIG. 21A.

Subsequently, by performing wet etching processing using hydrogen fluoride (HF) or the like on the top surface 35 of the columnar pattern CL25, the top surface 35 of the columnar pattern CL25 is roughened as shown in FIG. 21B. Thereby, as shown in FIG. 21B, a roughened surface structure 46 is formed on the top surface 35 of the columnar pattern CL25. Thereafter, the process of removing the patterned resist 71 from the template 10 is performed in the same manner as in the first embodiment, and the formation of the actual pattern AC on the template 10 is completed.

### 2.3 Actions and Effects of Using Template of Present Embodiment

According to such a configuration, since the surface area of the top surface 35 of the columnar pattern CL25 may be made larger than the surface area of the respective top surfaces 31 to 34 of the other columnar patterns CL21 to CL24, the same or similar action and effect as the template 10 in the first embodiment may be obtained.

### 3. Other Embodiments

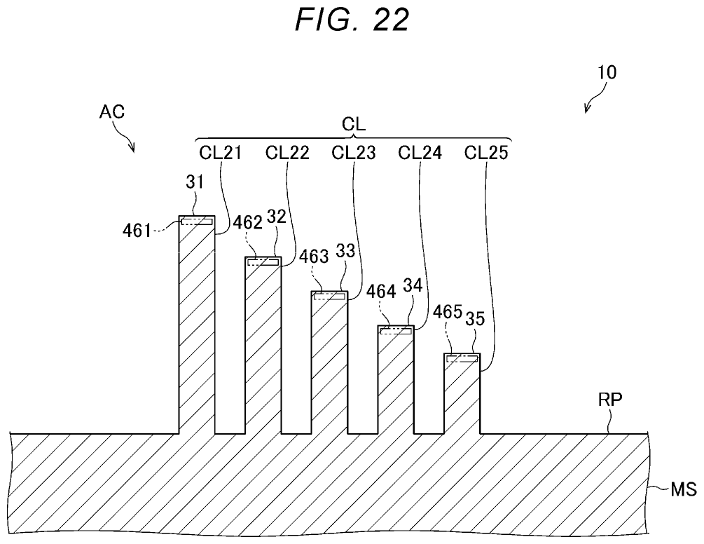

The present disclosure is not limited to the above specific examples. For example, the template 10 of the second embodiment is not limited to the structure in which the roughened surface structure 46 is formed only on the top surface 35 of the columnar pattern CL25, roughened surface structures 461 to 465 may be formed on the top surfaces 31 to 35 of all the columnar patterns CL21 to CL25 as shown in FIG. 22, respectively. In this case, the roughened surface structures 461 to 465 may be formed so that the surface roughness gradually increases in this order. As a result, the columnar patterns CL21 to CL25 are formed so that the surface area of the top surface increases as the protrusion amount decreases. Therefore, as the resist material 91 moves from the columnar pattern CL21 to the columnar pattern CL25, the affinity of the top surfaces 31 to 35 of the columnar patterns CL21 to CL25 with respect to the resist material 91 is gradually increased. Therefore, since the resist material 91 may more easily permeate, it is possible to prevent the occurrence of regions not filled with the resist material 91.

The roughened surface structures 461 to 464 formed on the respective top surfaces 31 to 34 of the columnar patterns CL21 to CL24 shown in FIG. 22 have substantially the same surface roughness, and the roughened surface structure 465 formed on the top surface 35 of the columnar pattern CL25 may have surface roughness larger than the roughened surface structures 461 to 464. With such a configuration, since the surface area of the top surface 35 of the columnar pattern CL25 may be made larger than the surface area of the respective top surfaces 31 to 34 of the other columnar patterns CL21 to CL24, the same or similar action and effect as the template 10 in the second embodiment may be obtained.

An uneven structure may be formed on each of the top surfaces 31 to 35 of the columnar patterns CL21 to CL25. In this case, the top surface 35 of the columnar pattern CL25 may be provided with an uneven structure larger than the uneven structure formed on the top surfaces 31 to 34 of the other columnar pattern CL21 to CL24, for example, an uneven structure with a projection having a higher height or an uneven structure with a higher number of projections.

The number of columnar patterns forming the actual pattern AC of the template 10 is not limited to five, and may be any number of two or more with different protrusion amounts. For example, when at least three columnar patterns are formed on the template 10, if at least three columnar patterns are formed so that the surface area of the top surface increases as the protrusion amount decreases, the same or similar action and effect as the template 10 in each embodiment may be obtained.

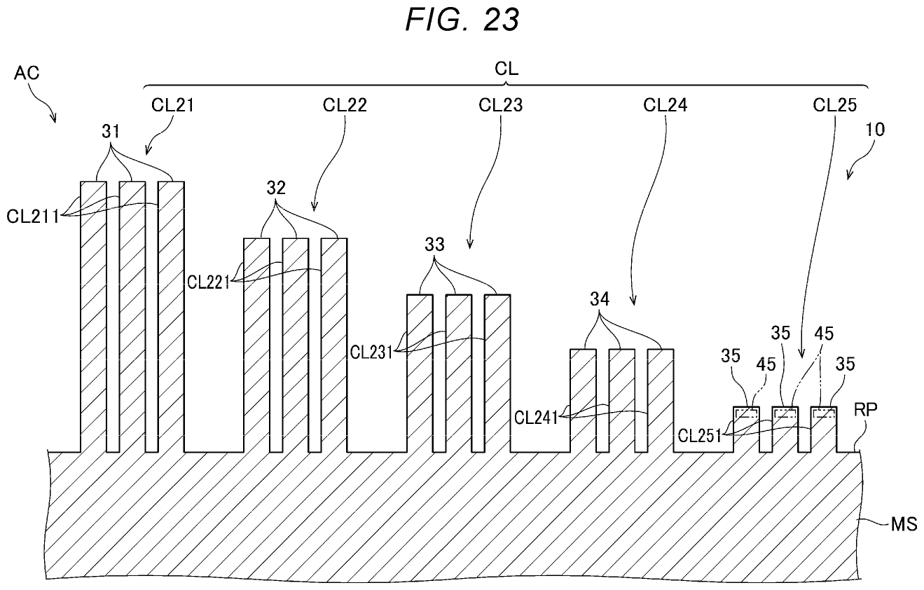

As shown in FIG. 23, for example, the columnar patterns CL21 to CL25 may each include three protruding pieces CL211, CL221, CL231, CL241, and CL251 having the same shape. For example, the three protruding pieces CL251 have substantially the same protrusion amount from the reference plane RP of the mesa portion MS and are arranged with a predetermined gap therebetween. In this case, the uneven structure 45 may be formed on the top surface 35 of each of the three protruding pieces CL251. Instead of the uneven structure 45, the roughened surface structure 46 as in the second embodiment may be formed on the top surface 35 of each of the three protruding pieces CL251.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A template configured to transfer a pattern to a resin applied to a substrate, the template comprising:
a base material; and
a mesa portion protruding from a surface of the base material, wherein
the mesa portion includes a plurality of protruding portions protruding from a reference plane of the mesa portion,
the plurality of protruding portions include at least a first protruding portion and a second protruding portion, in which a protrusion amount of the second protruding portion with respect to the reference plane is smaller than a protrusion amount of the first protruding portion with respect to the reference plane, and
a surface area of a top surface of the second protruding portion is larger than a surface area of a top surface of the first protruding portion.

2. The template according to claim 1, wherein
surface roughness of the top surface of the second protruding portion is greater than surface roughness of the top surface of the first protruding portion.

3. The template according to claim 1, wherein,
on the top surface of the second protruding portion, an uneven structure that is not formed on the top surface of the first protruding portion, or an uneven structure that is larger than an uneven structure formed on the top surface of the first protruding portion is formed.

4. The template according to claim 3, wherein
a height of a projection provided in the uneven structure formed on the top surface of the second protruding portion is shorter than a protrusion amount of the second protruding portion from the reference plane of the mesa portion.

5. The template according to claim 3, wherein
a width of a gap formed between a plurality of projections provided in the uneven structure formed on the top surface of the second protruding portion is narrower than a width of a gap formed between the plurality of second protruding portions.

6. The template according to claim 1, further comprising:
at least three protruding portions having different protrusion amounts with respect to the reference plane as the plurality of protruding portions, wherein
the at least three protruding portions are formed so that the surface area of the top surface increases as the protrusion amount decreases.

7. The template according to claim 1, wherein
the plurality of protruding portions include a plurality of protruding pieces that have the same protrusion amount with respect to the reference plane and are arranged with a predetermined gap from each other.

8. The template according to claim 1, wherein
the top surface of the second protruding portion has wettability such that a contact angle with respect to an organic material is equal to or less than 90 degrees.

9. The template according to claim 1, wherein
the top surface of the second protruding portion has wettability such that a contact angle with respect to an organic material is equal to or less than 65 degrees.

10. A method for manufacturing a template capable of transferring a pattern to a resin applied to a substrate, the method comprising:
processing a surface of a base material to form a mesa portion protruding from the base material;
forming a plurality of protruding portions including a first protruding portion and a second protruding portion, in which a protrusion amount of the second protruding portion with respect to the reference plane is smaller than a protrusion amount of the first protruding portion with respect to the reference plane; and
treating a top surface of the second protruding portion so that a surface area of the top surface of the second protruding portion is larger than a surface area of a top surface of the first protruding portion.

11. The method for manufacturing a template according to claim 10, wherein the step of treating a top surface of the second protruding portion further comprises:
forming an uneven structure on the top surface of the second protruding portion.

12. The method for manufacturing a template according to claim 10, wherein the step of treating a top surface of the second protruding portion further comprises:
roughening the top surface of the second protruding portion.

13. A method for manufacturing a semiconductor device comprising:
transferring a pattern to a resin applied on a substrate by using a template, wherein the template comprises:
a base material; and
a mesa portion protruding from a surface of the base material, wherein
the mesa portion includes a plurality of protruding portions protruding from a reference plane of the mesa portion,
the plurality of protruding portions include at least a first protruding portion and a second protruding portion, in which a protrusion amount of the second protruding portion with respect to the reference plane is smaller than a protrusion amount of the first protruding portion with respect to the reference plane, and
a surface area of a top surface of the second protruding portion is larger than a surface area of a top surface of the first protruding portion;
forming a patterned resist; and
processing the substrate based on the patterned resist.
